(19) United States
(12) Patent Application Publication
(10) Pub. No.: US 2009/0140360 A1
(43) Pub. Date: Jun. 4, 2009

(54) IMAGE SENSOR AND FABRICATING METHOD THEREOF

(76) Inventor: Young-Je Yun, Ansan-si (KR)

Correspondence Address: SHERR & VAUGHN, PLLC, 620 HERNDON PARKWAY, SUITE 200, HERNDON, VA, 20170, US

(21) Appl. No.: 12/253,254

(22) Filed: Oct. 17, 2008

(30) Foreign Application Priority Data
Nov. 30, 2007 (KR) 10-2007-0123619

(51) Int. Cl. H01L 31/18; H01L 31/102

(52) U.S. Cl. 257/432; 438/70; 257/E31.127; 257/E31.055

(57) ABSTRACT

An image sensor and fabricating method thereof may include a semiconductor substrate, a plurality of photodiodes formed on and/or over the semiconductor substrate, a first insulating layer formed on and/or over the semiconductor substrate including the plurality of photodiodes, at least one metal line formed on and/or over the first insulating layer, a second insulating layer having a plurality of wells formed on and/or over the plurality of photodiodes, a plurality of color filters formed by embedding color filter layers in a plurality of the wells, and a plurality of microlenses formed on and/or over the color filters.

The present application claims priority under 35 U.S.C. 119 to Korean Patent Application No. 10-2007-0123619 (filed on Nov. 30, 2007), which is hereby incorporated by reference in its entirety.

### BACKGROUND

Generally, an image sensor is a semiconductor device that converts an optical image to an electric signal. Image sensors can be categorized into CCDs (charge coupled devices) and CMOS (complementary metal oxide silicon) devices. Image sensors include a light receiving area having a photodiode for sensing light and a logic area for processing the sensed light into an electric signal which may be turned into data. Many efforts are ongoing to raise light sensitivity.

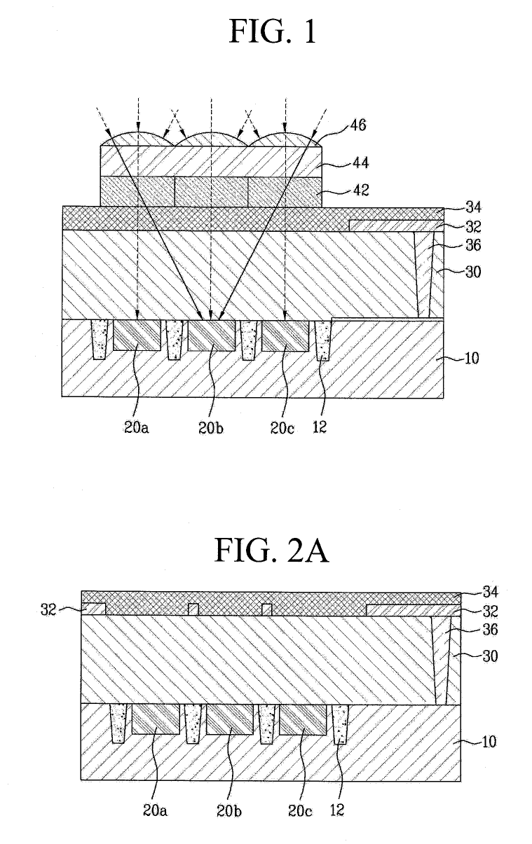

FIG. 1 is a cross-sectional diagram of CMOS image sensor 1 showing a light receiving area including photodiodes 20a, 20b and 20c. Referring to example FIG. 1, image sensor 1 may include a plurality of photodiodes 20a, 20b and 20c, and a device isolation layer (shallow trench isolation, or “STI”) 12 for isolating a plurality of the photodiodes 20a, 20b and 20c from each other. First and second insulating layers 30 and 34 may be formed over a semiconductor substrate 10. A metal line 32 may be electrically connected to a logic area in the second insulating layer 34. A contact 36 may electrically connect the metal line 32 to another area. A color filter layer 42 including red (R), blue (B) and green (G) may be formed over the second insulating layer 34 opposite each of a plurality of the photodiodes 20a, 20b and 20c. A planarizing layer 44 may be formed over the color filter layer 42, and a microlens 46 may be formed over the planarizing layer 44 opposite the color filter layer 42 including red (R), blue (B) and green (G).

As the pixel pitch of a CMOS image sensor is reduced, a photodiode may fail to be completely focused even if an optimal microlens is formed. This is because a condensable minimum spot size in an optimal focus condition is the size of the airy disc, which is proportional to 1/NA and the focal distance. In this case, the NA (numerical aperture) means the aperture of an iris.

In a pixel in a CMOS image sensor, the NA corresponds to the pixel pitch and the focal distance corresponds to a metal line layer thickness. To obtain a focal spot of the same size, the thickness of the metal line layer should decrease in proportion to the decrease in pixel size in a given CMOS image sensor. However, the image sensor structure reaches a design limitation when the metal line is required to have a thickness smaller than a minimum thickness requirement dictated by other design rules. Hence, a pixel pitch limit is generated, preventing further reductions in pixel size. According to a computer simulated study result, the above optical limit is estimated to be reached in a pixel of about 1.75 μm.

### SUMMARY

Embodiments relate to a semiconductor device, and more particularly, to a CMOS image sensor and fabricating method thereof. Embodiments relate to an image sensor and fabricating method thereof, by which sensitivity of the image sensor can be raised by increasing light condensing efficiency of a microlens by effectively decreasing a vertical distance between a photodiode and the microlens of the image sensor. Embodiments relate to an image sensor and fabricating method thereof, by which light can be condensed at the same level of other image sensors using a microlens having a greater thickness than that of other microlenses.

Embodiments relate to a method of fabricating an image sensor which may include providing a semiconductor substrate, forming a plurality of photodiodes over the semiconductor substrate, forming a first insulating layer over the semiconductor substrate including the plurality of photodiodes, forming at least one metal line over the first insulating layer, forming a second insulating layer over the first insulating layer including the at least one metal line, forming a plurality of wells over the plurality of photodiodes by etching the second insulating layer, filling the plurality of wells with color filter layers to form a plurality of color filters, and forming a plurality of microlenses over the plurality of color filters.

Embodiments relate to an image sensor which may include a semiconductor substrate, a plurality of photodiodes formed over the semiconductor substrate, a first insulating layer over the semiconductor substrate including the plurality of photodiodes, at least one metal line formed over the first insulating layer, a second insulating layer having a plurality of wells formed over the plurality of photodiodes, a plurality of color filters formed by embedding color filter layers in a plurality of the wells, and a plurality of microlenses formed over the color filters.

Embodiments relate to a method of fabricating an image sensor which may include forming a plurality of photodiodes over a semiconductor substrate, forming a first insulating layer over the semiconductor substrate including the plurality of photodiodes, forming at least one metal line over the first insulating layer, forming a plurality of wells in the first insulating layer over the plurality of photodiodes, forming a plurality of color filters by disposing color filter layers in the plurality of wells, forming a second insulating layer over the first insulating layer including the at least one metal line and the plurality of color filters, and forming a plurality of microlenses over the color filters.

Embodiments relate to an image sensor which may include a semiconductor substrate, a plurality of photodiodes formed over the semiconductor substrate, a first insulating layer including a plurality of etched wells over the plurality of photodiodes, at least one metal line over the first insulating layer, a plurality of color filters formed by color filter layers formed in the plurality of etched wells, a second insulating layer over the first insulating layer including the at least one metal line and the plurality of color filters, and a plurality of microlenses formed over the plurality of color filters.

Accordingly, embodiments may provide the following effects and/or advantages. Unlike other CMOS image sensors, a plurality of wells formed within a second insulating layer may be filled up with color filters. A microlens is directly formed without forming a planarizing layer between the color filters. Therefore, sensitivity of the image sensor can be optimized by increasing light condensing efficiency of a microlens by effectively decreasing a vertical distance between a photodiode and the microlens of the image sensor. In addition, light can be condensed at the same level of others using a microlens having a greater thickness than that of other microlenses. Therefore, a thickness margin for forming a microlens can be enhanced in a microlens forming process.

### DRAWINGS

Example FIG. 1 is a cross-sectional diagram of a CMOS image sensor.

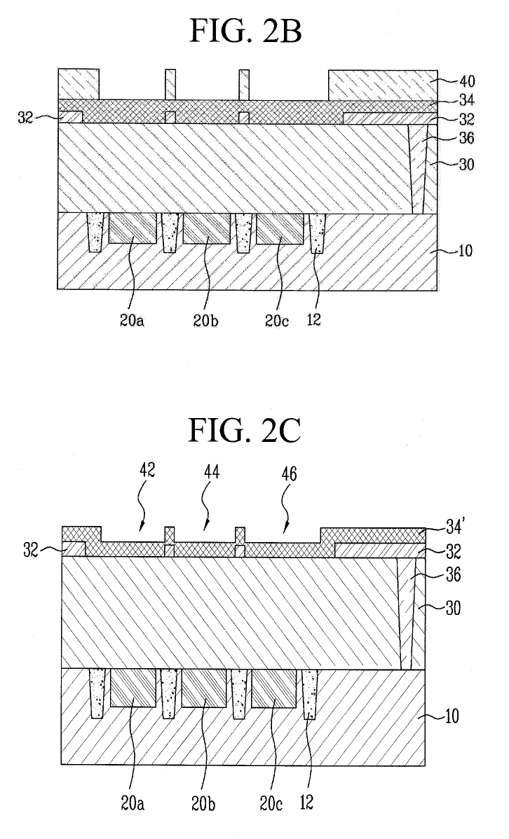

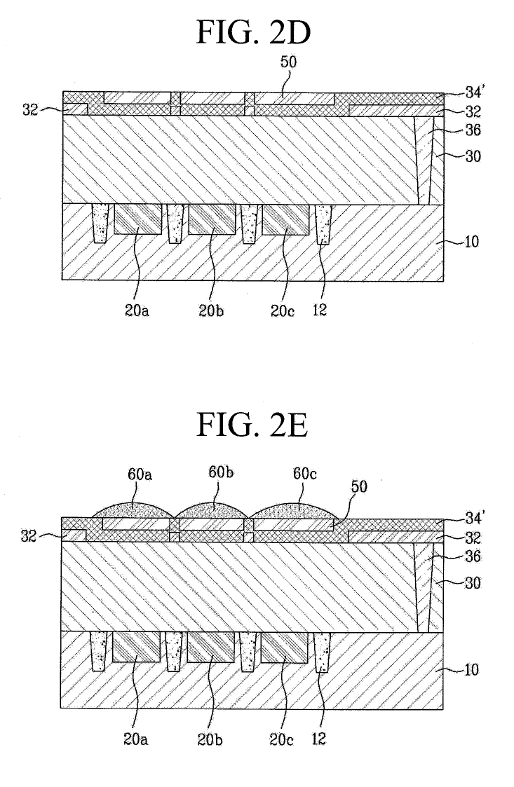

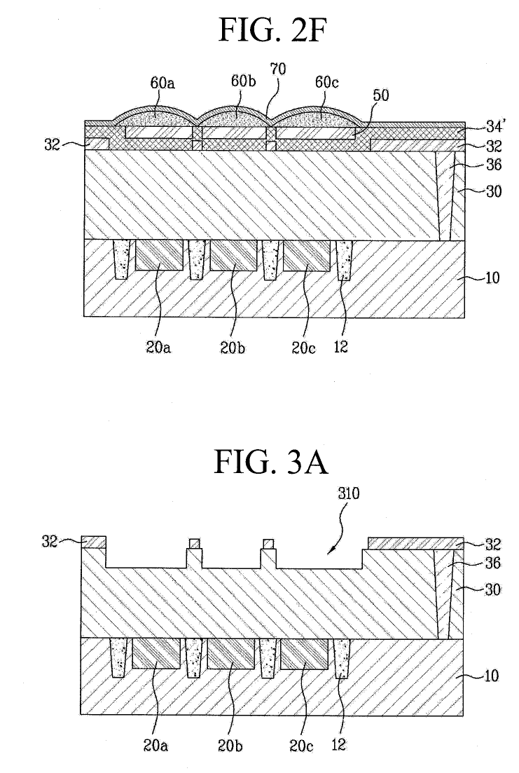

Example FIGS. 2A to 2F are cross-sectional diagrams for a method of fabricating an image sensor according to embodiments.

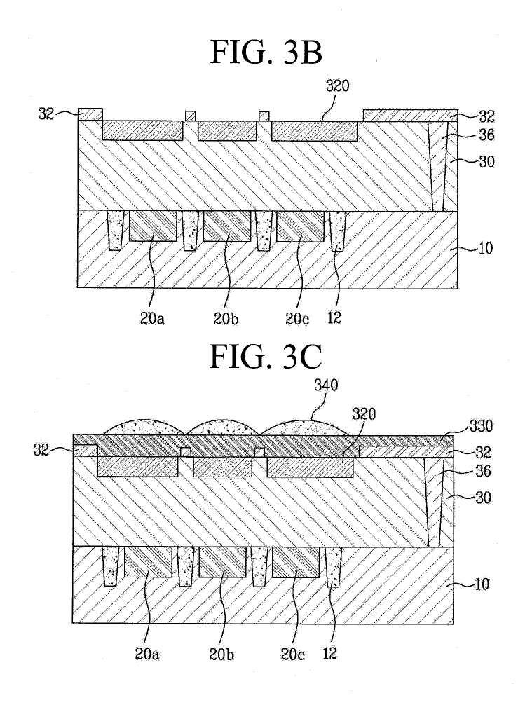

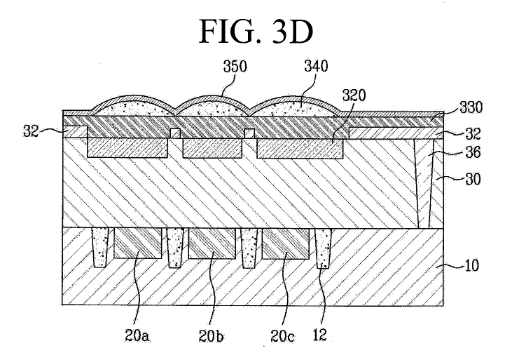

Example FIGS. 3A to 3D are cross-sectional diagrams for a method of fabricating an image sensor according to embodiments.

### DESCRIPTION

Example FIGS. 2A to 2F are cross-sectional diagrams for a method of fabricating an image sensor according to embodiments.

Referring to example FIG. 2A, a plurality of photodiodes 20a, 20b and 20c may be formed over semiconductor substrate 10. A device isolation layer (shallow trench isolation) 12 may then be formed to isolate photodiodes 20a, 20b and 20c from each other. Alternatively, after device isolation layer 12 has been formed in semiconductor substrate 10, a plurality of photodiodes 20a, 20b and 20c may be formed. First insulating layer 30 may be formed of a transparent substance on and/or over the semiconductor substrate 10 having a plurality of photodiodes 20a, 20b and 20c formed therein. A trench may be formed in a portion of first insulating layer 30 by a photolithographic etch using a mask. The trench may be filled with an electrically conductive substance (e.g., Al, Cu, etc.) to form contact 36. Metal line 32 connected to another area may be formed on and/or over first insulating layer 30, overlapping contact 36. Metal line 32 and contact 36 may play a role in electrically connecting logic and light-receiving areas together. Second insulating layer 34 may be formed by depositing (coating) a transparent substance on and/or over first insulating layer 30 having metal line 32 formed thereon.

Referring to example FIG. 2B, photoresist pattern 40 may be formed on and/or over second insulating layer 34 to correspond to metal line 34. Photoresist pattern 40 may be patterned to expose a partial area of second insulating layer 34 corresponding to photodiodes 20a, 20b and 20c. In particular, photoresist pattern 40 may be patterned to form color filters corresponding to photodiodes 20a, 20b and 20c, respectively.

Referring to example FIG. 2C, a plurality of wells 42, 44 and 46 may be formed to a prescribed depth in second insulating layer 34 by etching second insulating layer 34 using photoresist pattern 40 as an etch mask. For instance, each well 42, 44 and 46 may be formed between the metal lines. The depth of each of well 42, 44 and 46 may be in a range between approximately 100 nm to 1,000 nm, and more particularly, in a range between approximately 600 nm to 700 nm, which may correspond to the thickness of the color filter layer.

Referring to example FIG. 2D, color filter 50 may be formed in each well 42, 44 and 46 of second insulating layer 34 to correspond to each photodiode 20a, 20b and 20c. For instance, a blue color filter, a green color filter and a red color filter can be provided in wells 42, 44 and 46 to correspond to photodiodes 20a, 20b and 20c, respectively. With regard to photodiodes 20a, 20b and 20c, light traveling through the green (G) color filter may be received by first photodiode 20a, light traveling through the blue (B) color filter may be received by second photodiode 20b, and light traveling through the red (R) color filter may be received by third photodiode 20c.

Referring to FIG. 2E, microlenses 60a, 60b and 60c may be formed on and/or over color filter layer 50 and correspond to color filters 50, respectively. Microlenses 50a, 60b and 60c may be formed having a hemispherical cross-section by performing a reflow process at a temperature in a range between approximately 120° C. to about 200° C. Microlenses 60a, 60b and 60c may be hardened by applying UV ray thereto.

Referring to example FIG. 2F, protective layer 70 may be formed on and/or over microlenses 60a, 60b and 60c to protect from moisture and scratches. Since a substance of protective layer 70 may have a refraction index (e.g., in a range between approximately 1.6 to 1.7) almost equal to that of microlenses 60a, 60b, 60c for visible ray wavelengths, optical refraction may be minimized between protective layer 70 and microlenses 60a, 60b, 60c.

Comparing the image sensor fabricated by the method according to embodiments to the image sensor shown in example FIG. 1, the color filter layers may be embedded in the second insulating layer. The planarizing layer formed over the color filter layers may be omitted. Therefore, embodiments may reduce the distance between photodiodes 20 and microlens 60 in a range between approximately 1 μm to 2 μm. Therefore, the photodiode may be in substantially complete focus with a thicker microlens than other microlenses. Since the distance between photodiodes 20 and microlenses 60 may be reduced, light loss may be decreased and a light condensing function may be relatively increased, whereby sensitivity of the image sensor can be maximized.

Example FIG. 2F is a cross-sectional diagram of a light-receiving area of an image sensor fabricated by a method according to embodiments. Referring to example FIG. 2F, an image sensor may include a plurality of photodiodes 20a, 20b and 20c provided to a semiconductor substrate to convert incident light to an electric signal. First insulating layer 30 may be formed on and/or over semiconductor substrate 10 having photodiodes 20a, 20b and 20c. Metal line 32 may be formed on and/or over first insulating layer 30. Second insulating layer 34′ may be formed with a plurality of wells on and/or over first insulating layer 30 including metal line 32. Color filter layers 50 may be provided in a plurality of the wells opposite the plurality of photodiodes 20a, 20b and 20c, respectively. A plurality of microlenses 60a, 60b and 60c may be provided to correspond to color filter layers 50, respectively. Accordingly, the image sensor of embodiments shown in example FIG. 2F differs from the image sensor shown in example FIG. 1 in that the color filters may be embedded in the wells of the second insulating layer. Microlenses 60a, 60b and 60c may be directly formed without forming the planarizing layer between color filter layers 50. Therefore, embodiments reduce the distance between microlens 60a, 60b, 60c and photodiode 20a/20b/20c in a range between approximately 1 μm to about 2 μm. Accordingly, light condensing efficiency of the microlens may be increased, thereby raising the sensitivity of the image sensor. Moreover, since embodiments achieve the light condensing ability at the same level of other using a thicker microlens than the other microlens, the allowable margin of variation in the thickness of the microlens can be enhanced during formation of the microlens.

Example FIGS. 3A to 3D are cross-sectional diagrams for a method of fabricating an image sensor according to embodiments, in which steps up to forming metal line 32 are essentially the same as those illustrated and described in example FIGS. 2A to 2F.

Referring to example FIG. 3A, plurality of wells 310 may be formed to a prescribed depth in first insulating layer 30, on and/or over which metal line 32 is formed, by photolithography using a mask. Wells 310 may be formed opposite photodiodes 20a, 20b and 20c, respectively. The depth of each of well 310 may be in a range between approximately 100 nm to 1,000 nm, and more particularly, in a range between approximately 600 nm to 700 nm, which may correspond to a thickness of a color filter layer.

Referring to example FIG. 3B, each well 310 formed in first insulating layer 30 may be filled with color filter layer 320. Referring to example FIG. 3C, second insulating layer 330 may be formed with a transparent substance on and/or over first insulating layer 30 including metal line 32 and color filter layers 320.

Referring to example FIG. 3D, microlenses 340 may be formed on and/or over second insulating layer 330 and corresponding to color filter layers 320. Protective layer 350 may be formed on and/or over microlenses 340 to protect microlenses 340 and/or color filter layers 320 from moisture and scratches. Accordingly, an image sensor according to embodiments may include plurality of photodiodes 20a, 20b and 20c provided on and/or over semiconductor substrate 10 to convert incident light to an electric signal. First insulating layer 30 may be formed on and/or over semiconductor substrate 10 with photodiodes 20a, 20b and 20c formed thereon and/or thereover. Metal line 32 may be formed on and/or over first insulating layer 30. Color filter layers 320 may be embedded in a plurality of wells formed by etching first insulating layer 30 opposite a plurality of photodiodes 20a, 20b and 20c. Second insulating layer 330 may be formed on and/or over first insulating layer 30 including metal line 32 and the filer layers 320. A plurality of microlenses 340 may be formed on and/or over second insulating layer 330 to correspond to color filter layers 320. The image sensor according to embodiments can further include another protective layer formed on and/or over microlenses 340 to protect microlenses 340 and/or color filter layers 320 from moisture or scratches. The image sensor shown in example FIG. 3D according to embodiments, like the image sensor shown in example FIG. 2F, can reduce the distance between the microlenses and corresponding photodiodes. Accordingly, light condensing efficiency of the microlens may be increased, thereby raising the sensitivity of the image sensor.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
providing a semiconductor substrate; and then
forming a plurality of photodiodes in the semiconductor substrate; and then
forming a first insulating layer over the semiconductor substrate including the plurality of photodiodes; and then
forming at least one metal line over the first insulating layer; and then
forming a second insulating layer over the first insulating layer including the at least one metal line; and then
forming a plurality of wells over the plurality of photodiodes by etching the second insulating layer; and then
filling the plurality of wells with color filter layers to form a plurality of color filters; and then
forming a plurality of microlenses over the plurality of color filters.

2. The method of claim 1, further comprising forming a protective layer over the microlenses.

3. The method of claim 2, wherein forming the plurality of wells comprises etching the second insulating layer to a depth in a range between approximately 600 nm to 700 nm.

4. The method of claim 2, wherein forming the protective layer comprises forming the protective layer to have substantially the same index of refraction for light in the visible spectrum as that of the microlenses.

5. The method of claim 1, wherein forming the microlenses comprises forming the microlenses having hemispherical cross-sections by performing a reflow process at a temperature in a range between approximately 120° C. to about 200° C.

6. An apparatus comprising:
a semiconductor substrate;
a plurality of photodiodes formed in the semiconductor substrate;
a first insulating layer formed over the semiconductor substrate including the plurality of photodiodes;
at least one metal line formed over the first insulating layer;
a second insulating layer formed over the first insulating layer including the at least one metal line;
a plurality of wells formed over and corresponding spatially to the plurality of photodiodes;
a plurality of color filters formed in a respective one of the plurality of the wells; and
a plurality of microlenses formed over and spatially corresponding to the color filters.

7. The apparatus of claim 6, further comprising a protective layer formed over the microlenses.

8. The apparatus of claim 7, wherein the protective layer is made of a material which protects the color filter layers and the microlenses from moisture and scratches.

9. The apparatus of claim 7 wherein each of the protective layer and the microlens is made of a material having substantially the same index of refraction for light in the visible spectrum.

10. The apparatus of claim 6, wherein the wells in the second insulating layer have a depth in a range between approximately 600 nm to 700 nm.

11. The apparatus of claim 6, further comprising a contact formed in the first insulating layer and electrically connected to the at least one metal line.

12. A method comprising:
forming a plurality of photodiodes in a semiconductor substrate; and then
forming a first insulating layer over the semiconductor substrate including the plurality of photodiodes; and then
forming at least one metal line over the first insulating layer; and then
forming a plurality of wells in the first insulating layer over and spatially corresponding to the plurality of photodiodes; and then
forming a plurality of color filters by forming color filter layers in the plurality of wells; and then
forming a second insulating layer over the first insulating layer including the at least one metal line and the plurality of color filters; and then
forming a plurality of microlenses over the color filters.

13. The method of claim 12, wherein forming the plurality of wells comprises etching the first insulating layer to a depth in a range between approximately 600 nm to 700 nm.

14. The method of claim 12, wherein forming the plurality of wells comprises etching the first insulating layer to a depth in a range between approximately 100 nm to 1,000 nm.

15. The method of claim 12, further comprising forming a protective layer over the microlenses.

16. The method of claim 15, wherein forming the protective layer comprises forming the protective layer to have substantially the same index of refraction for light in the visible spectrum as that of the microlenses.

17. The method of claim 12, further comprising, after forming the first insulating layer:
forming a trench in a portion of the first insulating layer; and then
filling the trench with an electrically conductive substance to form a form contact.

18. The method of claim 17, wherein the electrically conductive substance comprises at least one of aluminum and copper.

19. The method of claim 17, wherein the trench is formed by a photolithographic etch using a mask.

20. The method of claim 17, wherein the at least one metal line is electrically connected to the contact.
